(19) United States
(12) Patent Application Publication
(10) Pub. No.: US 2022/0097898 A1
(43) Pub. Date: Mar. 31, 2022

(54) TRAY FOR DISPLAY DEVICE

(71) Applicant: Samsung Display Co., LTD., Yongin-si (KR)

(72) Inventors: Hongju Kim, Hwaseong-si (KR); Kyeong-Min Kim, Asan-si (KR); Euiyoung Kim, Yongin-si (KR); Youngdae Song, Busan (KR); Junggil Oh, Hwaseong-si (KR); Nampyo Hong, Cheonan-si (KR)

(21) Appl. No.: 17/355,068

(22) Filed: Jun. 22, 2021

(30) Foreign Application Priority Data
Sep. 28, 2020 (KR) 10-2020-0126185

(51) Int. Cl. B65D 1/36; B65D 85/30; B65D 21/02

(52) U.S. Cl. CPC B65D 1/36; B65D 2585/6835; B65D 21/0215; B65D 85/30

(57) ABSTRACT

A tray for a display device includes a first support portion on which the display device, which includes a flexible circuit board including a driving chip, is disposed, the driving chip being mounted on a protruding portion of the flexible circuit board which protrudes to an outside of the display device and a second support portion spaced apart from the first support portion and on which the protruding portion of the flexible circuit board is disposed.

### CROSS-REFERENCE TO RELATED APPLICATION

This application claims priority from and the benefit of Korean Patent Application No. 10-2020-0126185 filed on Sep. 28, 2020, which is hereby incorporated by reference for all purposes as if fully set forth herein.

### BACKGROUND

### Field

Embodiments of the invention relate generally to a tray for a display device.

### Discussion of the Background

A display device includes a display panel, a cover window, and a flexible circuit board. The cover window may be disposed on a front surface of the display panel (e.g., a surface where an image is displayed), and the flexible circuit board may be disposed on a rear surface of the display panel (e.g., a surface where an image is not displayed) and the flexible circuit board may extend outside the display panel. Components of the display device are integrated through an assembly process.

When the display device is moved from a manufacturing line to an assembly line or transferred from an external company, a tray is used to safely transport the display device. The tray may include a support portion having a concave shape to safely transport the display device, and a display device may be disposed on the support portion. In addition, a plurality of trays may be stacked by stacking trays equipped with the display devices.

The above information disclosed in this Background section is only for understanding of the background of the inventive concepts, and, therefore, it may contain information that does not constitute prior art.

### SUMMARY

Embodiments provide a tray for a display device.

Additional features of the inventive concepts will be set forth in the description which follows, and in part will be apparent from the description, or may be learned by practice of the inventive concepts.

A tray for a display device according to embodiments may include a first support portion on which the display device, which includes a flexible circuit board including a driving chip, is disposed, the driving chip being mounted on a protruding portion of the flexible circuit board which protrudes to an outside of the display device and a second support portion spaced apart from the first support portion and on which the protruding portion of the flexible circuit board is disposed.

In an embodiment, the display device may contact an upper surface of the first support portion, and the protruding portion of the flexible circuit board contacts an upper surface of the second support portion.

In an embodiment, the display device may further include an inclined portion extending from an upper surface of the first support portion to an upper surface of the second support portion and inclined at a predetermined angle with respect to the upper surface of the first support portion.

In an embodiment, the first support portion, the inclined portion, and the second support portion may be continuously arranged and integrally formed.

In an embodiment, the inclined portion and the flexible circuit board may be spaced apart from each other.

In an embodiment, the inclined portion and the display device may be spaced apart from each other.

In an embodiment, an inclination angle of the inclined portion with respect to the first support portion may be determined so that the inclined portion is spaced apart from the display device.

In an embodiment, the inclination angle may be a right angle.

In an embodiment, the second support portion may include an inclined surface extending in a direction from the second support portion to the first support portion.

In an embodiment, the inclined surface and the flexible circuit board may be spaced apart from each other.

In an embodiment, the inclined surface and the display device may be spaced apart from each other.

In an embodiment, an inclination angle of the inclined surface with respect to the first support portion may be determined so that the inclined surface is spaced apart from the display device.

In an embodiment, the inclination angle may be a right angle.

In an embodiment, an upper surface of the first support portion may be disposed at a lower level than an upper surface of the second support portion.

In an embodiment, the display device further may include a digitizer and a display panel.

In an embodiment, an area of the second support portion may be determined according to an area of the protruding portion of the flexible circuit board.

The tray for a display device of the present invention may seat the display device and a protruding portion of a flexible circuit board included in the display device. Accordingly, a movement of the display device may be prevented, and a damage of the flexible circuit board due to the movement may be prevented.

In addition, an inclined portion or an inclined surface between the first support portion and the second support portion may be provided to prevent contact between the inclined portion or the inclined surface and the side surface of the display device or the protruding portion of the display device. Accordingly, a damage of the side surface of the display device or the protruding portion of the flexible circuit board may be prevented.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate illustrative embodiments of the invention, and together with the description serve to explain the inventive concepts.

FIG. 1 is a plan view illustrating a tray for a display device according to an embodiment of the present invention.

FIG. 2 is an enlarged plan view illustrating an area A of FIG. 1.

FIG. 3 is a plan view illustrating a shape in which a display device is disposed in a pocket portion of the tray of FIG. 2.

FIG. 4 is a cross-sectional view taken along a line I-I′ of FIG. 2.

FIG. 5 is a cross-sectional view taken along a line II-II′ of FIG. 3.

FIG. 6 is a cross-sectional view illustrating a tray for a display device according to another embodiment of the present invention.

FIG. 7 is a cross-sectional view illustrating a tray for a display device according to still another embodiment of the present invention.

FIG. 8 is a cross-sectional view illustrating a tray for a display device according to further still another embodiment of the present invention.

FIG. 9 is a cross-sectional view illustrating a tray for a display device according to further still another embodiment of the present invention.

FIG. 10 is a cross-sectional view illustrating a tray for a display device according to further still another embodiment of the present invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are illustrated in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing illustrative features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a tray for a display device in accordance with embodiments will be described in more detail with reference to the accompanying drawings. The same reference numerals are used for the same components in the drawings, and redundant descriptions of the same components will be omitted.

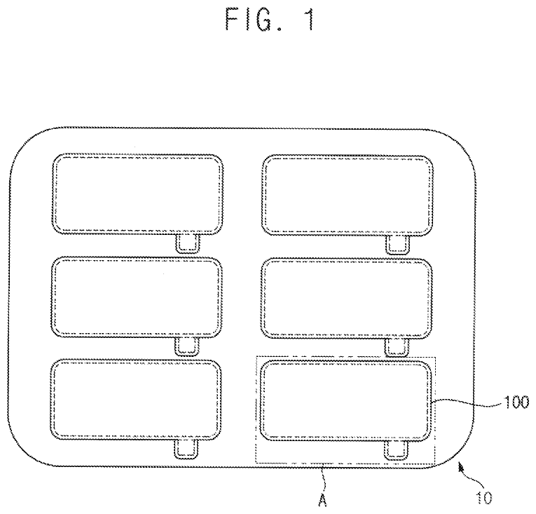

FIG. 1 is a plan view illustrating a tray for a display device according to an embodiment of the present invention.

Referring to FIG. 1, a tray 10 for a display device may include a plurality of pocket portions 100. Accordingly, the plurality of pocket portions 100 may be accommodated in one tray 10, so that the efficiency of storage and transportation of a display device 300 (illustrated in FIG. 3) may be improved. The number of pocket portions 100 illustrated in the drawings is six, but is not limited thereto. In addition, a plurality of trays 10 may be stacked by stacking the trays 10.

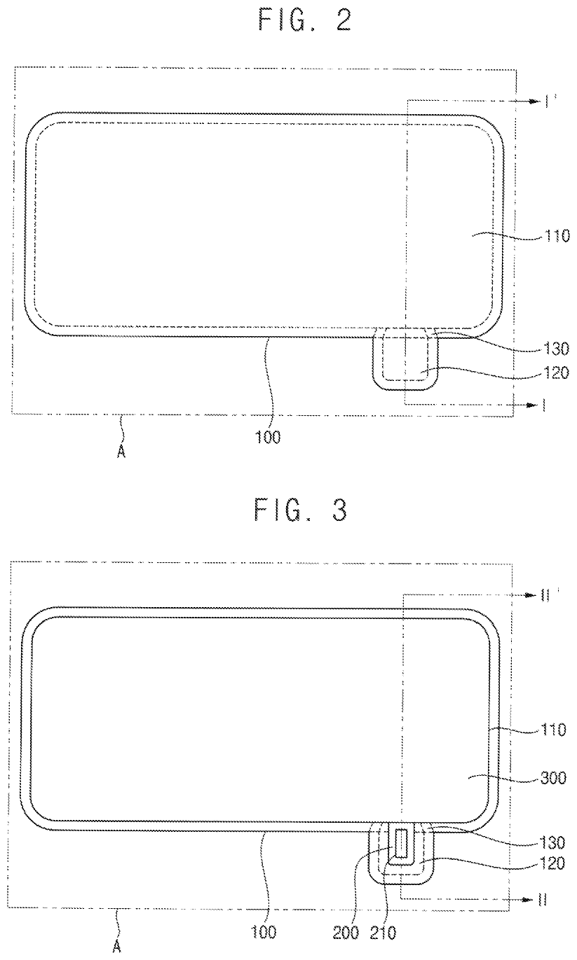

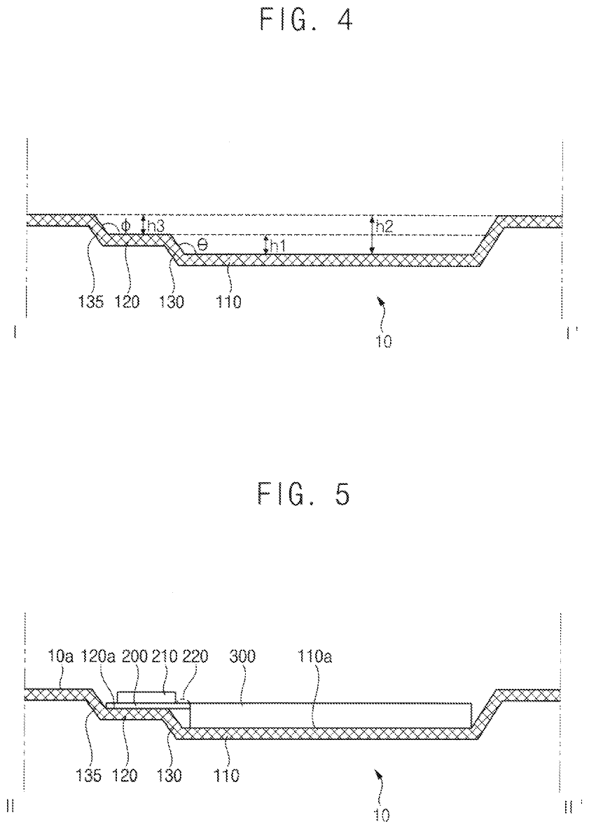

FIG. 2 is an enlarged plan view illustrating an area A of FIG. 1. FIG. 3 is a plan view illustrating a shape in which a display device is disposed in a pocket portion of the tray of FIG. 2. FIG. 4 is a cross-sectional view taken along a line I-I′ of FIG. 2. FIG. 5 is a cross-sectional view taken along a line II-II′ of FIG. 3.

As illustrated in FIG. 2 to FIG. 5, the tray 10 for a display device may include a first support portion 110, a second support portion 120, a first inclined portion 130, and a second inclined portion 135. The first support portion 110 and the second support portion 120 may be spaced apart from each other.

The display device 300 may be loaded on the display device tray 10. Here, the type of the display device 300 is not limited. For example, the display device 300 may include an organic light emitting display device, a liquid crystal display device, etc. The display device 300 may have a substantially rectangular planar shape.

The display device 300 may be accommodated in the first support portion 110. In other words, the display device 300 may be disposed on the first support portion 110. An upper surface 110a of the first support portion 110 may contact the display device 300. For example, the display device 300 may include a front surface on which an image is displayed and a rear surface opposite to the front surface. The upper surface 110a of the first support portion 110 and the front surface of the display device 300 may contact each other. The first support portion 110 may have substantially the same shape and area as the display device 300. The area of the first support portion 110 may be relatively bigger than the area of the display device 300 in consideration of the ease of the storage process. As illustrated in FIG. 3, the display device 300 may include a flexible circuit board 200 in which a driving chip 210 is mounted on a portion protruding from one side of the display device 300 to the outside of the display device 300.

The flexible circuit board 200 may be accommodated in the second support portion 120. In other words, the flexible circuit board 200 may be disposed on the second support 120 adjacent the second inclined portion 135. As illustrated in FIG. 5, the upper surface 120a of the second support portion 120 may contact the flexible circuit board 200. The flexible circuit board 200 may protrude to the outside of the display device 300 and the driving chip 210 may be mounted on the flexible circuit board 200. For example, the flexible circuit board 200 may include a front surface and a rear surface, and a portion of the front surface of the flexible circuit board 200 may contact the upper surface 120a of the second support portion 120. In addition, the driving chip 210 may be disposed on the rear surface of the flexible circuit board 200. The flexible circuit board 200 may extend and be connected to one side of the rear surface of the display device 300 and abut the second inclined portion 135 on the other side thereof. In addition, the flexible circuit board 200 may also exist on the rear surface of the display device 300. Hereinafter, a protruding portion of the flexible circuit board 200 is referred to as the flexible circuit board 200 for convenience.

As illustrated in FIG. 5, a portion of the flexible circuit board 200 that does not overlap with the driving chip 210 and is adjacent to the display device 300 may be defined as the neck portion 220 of the flexible circuit board 200. Because the driving chip 210 is not mounted on the neck portion 220, the neck portion 220 may be more easily damaged than a portion on which the driving chip 210 of the flexible circuit board 200 is mounted. While the display device 300 is loaded or transported inside the tray 10, the flexible circuit board 200 may move and the neck portion 220 may be easily damaged. In other words, when the display device 300 is stored and transported in the tray 10, lifting of the neck portion 220 may occur by an external impact.

Because the tray 10 according to the embodiment of the present invention includes the second support portion 120, the flexible circuit board 200 of the display device 300 may be supported by the second support portion 120. Accordingly, a damage to the neck portion 220 may be prevented.

In consideration of the ease of the storage process, and the like, an area of the second support portion 120 may be relatively greater than an area of the flexible circuit board 200. The area of the flexible circuit board 200 may be variously determined as desired. Accordingly, the area of the second support portion 120 may be determined according to the area of the flexible circuit board 200.

Referring to FIGS. 3, 4, and 5, each of the first support portion 110 and the second support portion 120 may be a portion of the tray 10. The first support portion 110 and the second support portion 120 may accommodate the display device 300 and the flexible circuit board 200. Accordingly, storage and transport of the display device 300 may be facilitated. The upper surface 110a of the first support portion 110 and the upper surface 120a of the second support portion 120 may be disposed at a level lower than the upper surface 10a of the tray 10. The second inclined portion 135 may be disposed between the upper surface 10a of the tray 10 and the second support portion 120.

The first inclined portion 130 may extend from the upper surface 110a of the first support portion 110 to the upper surface 120a of the second support portion 120. In addition, the first inclined portion 130 may be inclined at an angle θ with respect to the upper surface 110a of the first support portion 110. The first support portion 110, the first inclined portion 130, and the second support portion 120 may be continuously arranged and may be integrally formed.

The second inclined portion 135 may be inclined at an angle ϕ with respect to the upper surface 120a of the second support portion 120. The inclination angle ϕ of the second inclined portion 135 inclined at a predetermined angle with respect to the first support portion 110 may be greater than about 90 degrees and less than about 180 degrees.

Because the first inclined portion 130 is arranged between the first support portion 110 and the second support portion 120, a height difference h1 between the upper surface 110a of the first support portion 110 and the upper surface 120a of the second support portion 120 may be present. Due to this height difference h1, the display device 300 and the flexible circuit board 200 may contact the upper surface 110a of the first support portion 110 and the upper surface 120a of the second support portion 120, respectively. Because the flexible circuit board 200 contacts the upper surface 120a of the second support portion 120, the flexible circuit board 200 may not be moved up and down and left and right, and a damage such as bending of the flexible circuit board 200 may be prevented. Lateral movement of the flexible circuit board 200 may also be partially prevented by the second inclined portion 135.

The first inclined portion 130 is arranged between the first support portion 110 and the second support portion 120, so that the upper surface 110a of the first support portion 110 may be disposed at a lower level than the upper surface 120a of the second support portion 120. The front surface of the display device 300 in contact with the upper surface 110a of the first support portion 110 may be formed at a lower level than the front surface of the flexible circuit board 200 in contact with the upper surface 120a of the second support portion 120. Accordingly, the display device 300 and the flexible circuit board 200 may be easily disposed on the first support portion 110 and the second support portion 120, respectively.

The first inclined portion 130 may be spaced apart from the flexible circuit board 200. Because the first inclined portion 130 and the flexible circuit board 200 do not contact each other, the flexible circuit board 200 may not be damaged while the display device 300 is loaded or transported inside the tray 10. As a result, a defect in the display device 300 may not occur.

The first inclined portion 130 may be spaced apart from the display device 300. Because the first inclined portion 130 and the side surface of the display device 300 do not contact each other, the side surface of the display device 300 may not be damaged by the first inclined portion 130. The neck portion 220 of the flexible circuit board 200 keeps the display device 300 away from the first inclined portion 130. As a result, a defect in the display device 300 may not occur while the display device 300 is loaded or transported inside the tray 10.

In order to prevent damage to the display device 300 and the flexible circuit board 200 when the trays 10 are stacked, the height h2 of the tray 10 may be greater than the combined thickness of the display device 300, the flexible circuit board 200 and the thickness of the driving chip 210. In addition, in order to prevent the driving chip 210 from being damaged, the height difference h3 of the second inclined portion 135 between the upper surface 120a of the second support 120 and the upper surface 10a of the tray 10 may be greater than the combined thickness of the flexible circuit board 200 and the driving chip. However, when the height h2 of the tray 10 is excessively large, because the display device 300 may move largely up and down, the height h2 of the tray 10 may not be excessively large.

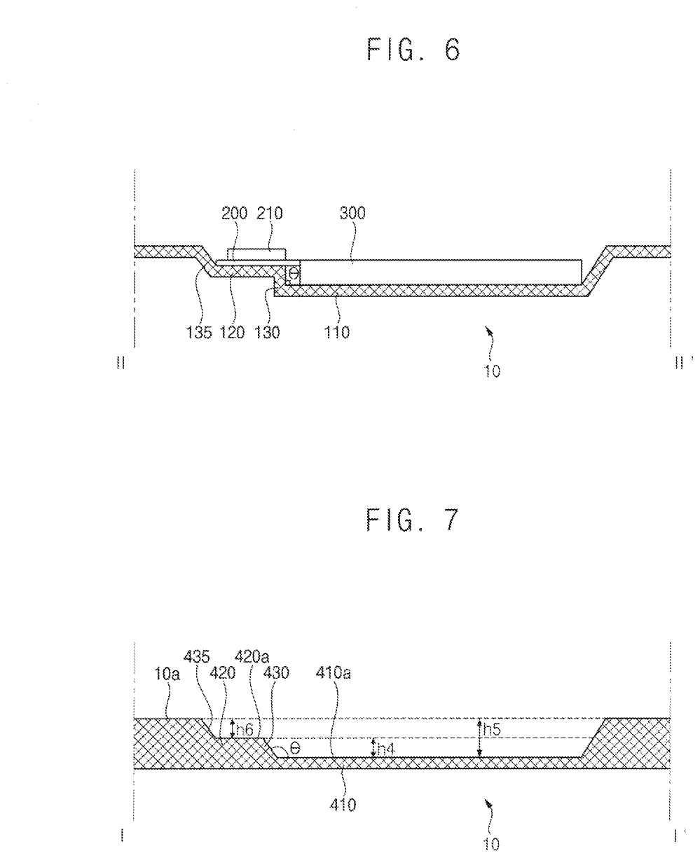

FIG. 6 is a cross-sectional view illustrating a tray for a display device according to another embodiment of the present invention.

Referring to FIG. 5 and FIG. 6, the inclination angle θ of the first inclined portion 130 inclined at a predetermined angle with respect to the first support portion 110 may be greater than about 90 degrees and less than about 180 degrees. The inclination angle θ may be determined according to the thickness of the display device 300 and the shape of the side surface of the display device 300. In order to separate the first inclined portion 130 and the display device 300 disposed on the first support portion 110, the inclination angle θ may be preferably greater than about 90 degrees.

The inclination angle θ of the first inclined portion 130 inclined at a predetermined angle with respect to the first support portion 110 may be about 90 degrees. When the inclination angle is about 90 degrees, the movement of the display device 300 may decrease compared to other angles, so that the flexible circuit board 200 may not be damaged.

FIG. 7 is a cross-sectional view illustrating a tray 10 for a display device according to another embodiment of the present invention.

Referring to FIG. 7, the second support portion 420 may include a first inclined surface 430 extending in a direction from the second support portion 420 to the first support portion 410 and a second inclined surface 435 extending from the second support portion 420 to the upper surface 10a of the tray 10. The first inclined surface 430 may be inclined at the angle θ with respect to the upper surface 410a of the first support portion 410. The second inclined surface 435 may be inclined at the angle ϕ and with respect to the upper surface 420a of the second support portion 420. The first support 410 and the second support 420 may not be integrally formed, and the second support 420 may be stacked on the upper surface 410a of the first support 410. The angle ϕ of the second inclined surface 435 may range between about 90 and 180 degrees.

Because the first inclined surface 430 is present on the side of the second support 420, a height difference h4 may exist between the upper surface 410a of the first support 410 and the upper surface 420a of the second support 420. Due to this height difference, the display device 300 and the flexible circuit board 200 may contact the upper surface 410a of the first support portion 410 and the upper surface 420a of the second support portion 420 respectively. Because the flexible circuit board 200 contacts the upper surface 420a of the second support portion 420 and is disposed adjacent the driving chip 210 and display device 300, the flexible circuit board 200 may not move vertically and horizontally, and a damage such as bending of the flexible circuit board 200 may be prevented.

Because the first inclined surface 430 exists on the side surface of the second support portion 420, the upper surface 410a of the first support portion 410 may be disposed at a level lower than the upper surface 420a of the second support portion 420. The front surface of the display device 300 in contact with the upper surface 410a of the first support portion 410 may be formed at a lower level than the front surface of the flexible circuit board 200 in contact with the upper surface 420a of the second support portion 420. As a result, the display device 300 and the flexible circuit board 200 may be easily disposed on the first support portion 410 and the second support portion 420, respectively.

The first inclined surface 430 may be spaced apart from the flexible circuit board 200. Because the first inclined surface 430 and the flexible circuit board 200 do not contact each other, the flexible circuit board 200 may not be damaged by the first inclined surface 430. As a result, a defect in the display device 300 may not occur.

The first inclined surface 430 may be spaced apart from the display device 300. Because the first inclined surface 430 and the side surface of the display device 300 do not contact each other, the side surface of the display device 300 may not be damaged by the first inclined surface 430. As a result, a defect in the display device 300 may not occur while the display device 300 is loaded or transported inside the tray 10.

In order to prevent damage to the display device 300 and the flexible circuit board 200 when the trays 10 are stacked, a height h5 of the tray 10 may be greater than the combined thickness of the display device 300 and the flexible circuit board 200 and the thickness of the driving chip 210. In addition, in order to prevent the driving chip 210 from being damaged, a height difference h6 of the second inclined surface 435 between the upper surface 420a of the second support portion 420 and the upper surface 10a of the tray 10 may be greater than the combined thickness of the flexible circuit board 200 and the driving chip 210. However, when the height h5 of the tray 10 is excessively large, because the display device 300 may move largely up and down. Therefore the height h5 of the tray 10 may preferably not be excessively large.

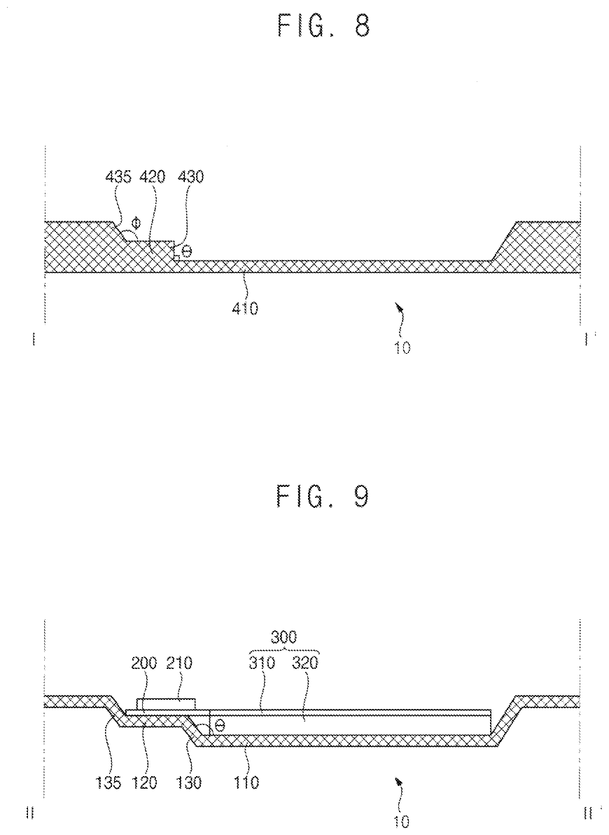

FIG. 8 is a cross-sectional view illustrating a tray for a display device according to another embodiment of the present invention.

In FIGS. 7 and 8, the inclination angle θ of the first inclined surface 430 inclined at a predetermined angle with respect to the first support portion 410 may be greater than about 90 degrees and less than about 180 degrees. The inclination angle θ may be determined according to the thickness of the display device 300 and the shape of the side surface of the display device 300. In order to separate the display device 300 disposed on the first inclined surface 430 and the first support portion 410, the inclination angle θ is preferably greater than about 90 degrees.

The inclination angle θ of the first inclined surface 430 inclined at a predetermined angle with respect to the first support portion 410 may be about 90 degrees. When the inclination angle is about 90 degrees, the movement of the display device 300 may decrease compared to other angles, so that the flexible circuit board 200 may not be damaged when the trays 10 are transported or stacked.

FIG. 9 is a cross-sectional view illustrating a tray for a display device according to another embodiment of the present invention.

Referring to FIG. 9, the display device 300 may include a digitizer 310 and a display panel 320. The digitizer 310 may be a device that converts coordinates of the input means into digital data. The digitizer 310 may use an electromagnetic resonance (EMR) method. The digitizer 310 may be connected to the flexible circuit board 200 and may be connected to other components of the display device 300 through the flexible circuit board 200. Although not illustrated, the display device may further include a cover window in addition to the digitizer 310 and the display panel 320.

A material of the tray 10 may include synthetic resin. The tray 10 may be made of ABS resin (acrylonitrile butadiene styrene copolymer). The material of the tray 10 is not particularly limited. The tray 10 may be manufactured by various plastic molding methods depending on the material.

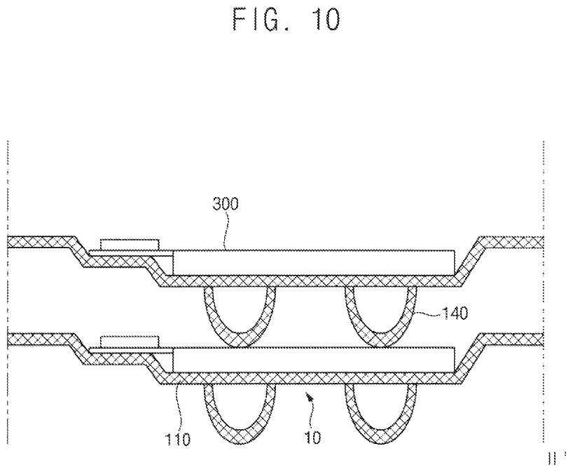

FIG. 10 is a cross-sectional view illustrating a tray 10 for a display device according to another embodiment of the present invention.

Referring to FIG. 10, the first support portion 110 may include a plurality of protruding portions 140 on the bottom of the tray 10 configured to prevent the trays 10 from moving during loading and transportation. The shape of each of the protruding portions 140 may not be limited, but may be convex downward to prevent damage to the display device 300 due to contact with the display device 300. The display devices 300 may include a protective cover disposed on a top surface thereof to prevent damage from the protruding portions 140.

Although described above with reference to the preferred embodiments of the present invention, those skilled in the art will understand that those skilled will be able to variously modify and change the present invention within the scope not departing from the spirit and scope of the present invention described in the following claims.

The tray for a display device according to embodiments of the present invention may be used to transport or store display devices such as an organic light emitting display device, and a liquid crystal display device.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A tray for a display device comprising:
a first support portion on which the display device, which includes a flexible circuit board including a driving chip, is disposed, the driving chip being mounted on a protruding portion of the flexible circuit board which protrudes to an outside of the display device; and
a second support portion spaced apart from the first support portion and on which the protruding portion of the flexible circuit board is disposed.

2. The tray for the display device of claim 1, wherein the display device contacts an upper surface of the first support portion, and the protruding portion of the flexible circuit board contacts an upper surface of the second support portion.

3. The tray for the display device of claim 1, further comprising:
an inclined portion extending from an upper surface of the first support portion to an upper surface of the second support portion and inclined at a predetermined angle with respect to the upper surface of the first support portion.

4. The tray for the display device of claim 3, wherein the first support portion, the inclined portion, and the second support portion are continuously arranged and integrally formed.

5. The tray for the display device of claim 3, wherein the inclined portion and the flexible circuit board are spaced apart from each other.

6. The tray for the display device of claim 3, wherein the inclined portion and the display device are spaced apart from each other.

7. The tray for the display device of claim 3, wherein an inclination angle of the inclined portion with respect to the first support portion is determined so that the inclined portion is spaced apart from the display device.

8. The tray for the display device of claim 7, wherein the inclination angle is a right angle.

9. The tray for the display device of claim 1, wherein the second support portion includes an inclined surface extending in a direction from the second support portion to the first support portion.

10. The tray for the display device of claim 9, wherein the inclined surface and the flexible circuit board are spaced apart from each other.

11. The tray for the display device of claim 9, wherein the inclined surface and the display device are spaced apart from each other.

12. The tray for the display device of claim 9, wherein an inclination angle of the inclined surface with respect to the first support portion is determined so that the inclined surface is spaced apart from the display device.

13. The tray for the display device of claim 12, wherein the inclination angle is a right angle.

14. The tray for the display device of claim 1, wherein an upper surface of the first support portion is disposed at a lower level than an upper surface of the second support portion.

15. The tray for the display device of claim 1, wherein the display device further includes a digitizer and a display panel.

16. The tray for the display device of claim 1, wherein an area of the second support portion is determined according to an area of the protruding portion of the flexible circuit board.
